(19) United States
(12) Patent Application Publication
(10) Pub. No.: US 2013/0215670 A1
(43) Pub. Date: Aug. 22, 2013

(54) MEMORY CIRCUIT AND FIELD PROGRAMMABLE GATE ARRAY

(71) Applicants: Masato ODA, Yokohama-Shi (JP); Koichiro ZAITSU, Kawasaki-Shi (JP); Kiwamu SAKUMA, Yokohama-Shi (JP); Shinichi YASUDA, Tokyo (JP); Kohei OIKAWA, Kawasaki-Shi (JP)

(72) Inventors: Masato ODA, Yokohama-Shi (JP); Koichiro ZAITSU, Kawasaki-Shi (JP); Kiwamu SAKUMA, Yokohama-Shi (JP); Shinichi YASUDA, Tokyo (JP); Kohei OIKAWA, Kawasaki-Shi (JP)

(21) Appl. No.: 13/719,775

(22) Filed: Dec. 19, 2012

(30) Foreign Application Priority Data
Feb. 17, 2012 (JP) 2012-32960

(51) Int. Cl. G11C 11/40

(52) U.S. Cl. CPC G11C 11/40
USPC 365/154

(57) ABSTRACT

A memory circuit according to an embodiment includes: a plurality of memory cells each having one pair of first and second nonvolatile memory circuits, each of the first and second nonvolatile memory circuits in each memory cell being capable of making a transition between a high resistance state and a low resistance state, and in a state in which one memory cell in the plurality of memory cells has information stored therein, one of the first and second nonvolatile memory circuits in the one memory cell being in a high resistance state whereas the other being in a low resistance state.

### CROSS-REFERENCE TO RELATED APPLICATION

This application is based upon and claims the benefit of priority from prior Japanese Patent Application No. 2012-32960 filed on Feb. 17, 2012 in Japan, the entire contents of which are incorporated herein by reference.

### FIELD

Embodiments described herein relate generally to a memory circuit and a field programmable gate array.

### BACKGROUND

The field programmable gate array (hereafter referred to as FPGA as well) is an IC capable of implementing an arbitrary logic function. A typical FPGA is configured by arranging basic tiles each including logic blocks (hereafter referred to as LBs as well) which implement basic logic information and a switch block (hereafter referred to as SB as well) which connects LBs arbitrarily. A memory is included in a circuit which constitutes each block, and the whole FPGA is caused to implement an arbitrary logic by rewriting data in the memories. If a dynamic reconfigurable circuit which rewrites the data stored in the memories faster than an operation frequency can be implemented, then a large logic which is usually calculated using several FPGAs can be calculated with one FPGA. Even if SRAM memories which can be rewritten fast are used in the above-described dynamic reconfigurable circuit, however, it is not possible to rewrite faster than the operation frequency.

The multi-context technique where memories of several kinds are mounted and they are changed over is known. In this multi-context technique, the same function as that of the dynamic reconfigurable circuit is implemented by executing the changeover faster than the operation frequency. As the current FPGA memory, it is a main stream to use a volatile SRAM. If the SRAM is used, it is necessary to keep the power supply turned on while the data is stored, resulting in a problem of large power dissipation.

If the SRAM is used as the memory in the dynamic reconfigurable circuit, various problems are caused as described later.

### BRIEF DESCRIPTION OF THE DRAWINGS

FIG. 1 is a circuit diagram showing a memory circuit according to a first reference example;

FIG. 2 is a circuit diagram showing a memory circuit according to a second reference example;

FIG. 3 is a circuit diagram showing a memory circuit according to a first embodiment;

FIG. 4 is a circuit diagram showing a memory circuit according to a modification of the first embodiment;

FIG. 5 is a circuit diagram showing a memory circuit according to a second embodiment;

FIG. 6 is a sectional view showing a nonvolatile memory transistor used in the memory circuit according to the second embodiment;

FIGS. 7(a) and 7(b) are diagrams for explaining states of a memory cell according to the second embodiment;

FIGS. 8(a) and 8(b) are diagrams for explaining writing into the memory cell according to the second embodiment;

FIG. 9 is a diagram showing drain current characteristics of the nonvolatile memory transistor;

FIG. 10 is a circuit diagram showing a memory circuit according to a third embodiment;

FIG. 11 is a circuit diagram showing a memory circuit according to a modification of the third embodiment;

FIGS. 12(a) and 12(b) are diagrams for explaining reading from the memory circuits according to the third embodiment and its modification;

FIG. 13 is a circuit diagram showing a memory circuit according to a fourth embodiment;

FIG. 14 is a circuit diagram showing a memory circuit according to a first concrete example of the fourth embodiment;

FIG. 15 is a diagram for explaining a case where writing of an FN tunnel current is conducted in the memory circuit according to the first concrete example of the fourth embodiment;

FIG. 16 is a circuit diagram showing a memory circuit according to a second concrete example of the fourth embodiment;

FIGS. 17(a) to 17(d) are schematic diagrams showing an FPGA according to a fifth embodiment; and

FIGS. 18(a) to 18(d) are schematic diagrams showing an FPGA according to a modification of the fifth embodiment.

### DETAILED DESCRIPTION

A memory circuit according to an embodiment includes: a plurality of memory cells each having one pair of first and second nonvolatile memory circuits, each of the first and second nonvolatile memory circuits having first to third terminals; a first power supply line connected to the first terminals of the first nonvolatile memory circuits; a second power supply line connected to the first terminals of the second nonvolatile memory circuits; an output line to which the second terminal of the first nonvolatile memory circuit and the second terminal of the second nonvolatile memory circuit in each memory cell are connected; a plurality of selection signal lines provided to be associated with the plurality of memory cells, the third terminal of the first nonvolatile memory circuit and the third terminal of the second nonvolatile memory circuit in an associated memory cell being connected to the associated selection signal line; and a switch circuit connected to the output line, each of the first and second nonvolatile memory circuits in each memory cell being capable of making a transition between a high resistance state and a low resistance state, and in a state in which one memory cell in the plurality of memory cells has information stored therein, one of the first and second nonvolatile memory circuits in the one memory cell being in a high resistance state whereas the other being in a low resistance state.

Before describing the embodiments, the course of events for achieving the embodiments will be described below.

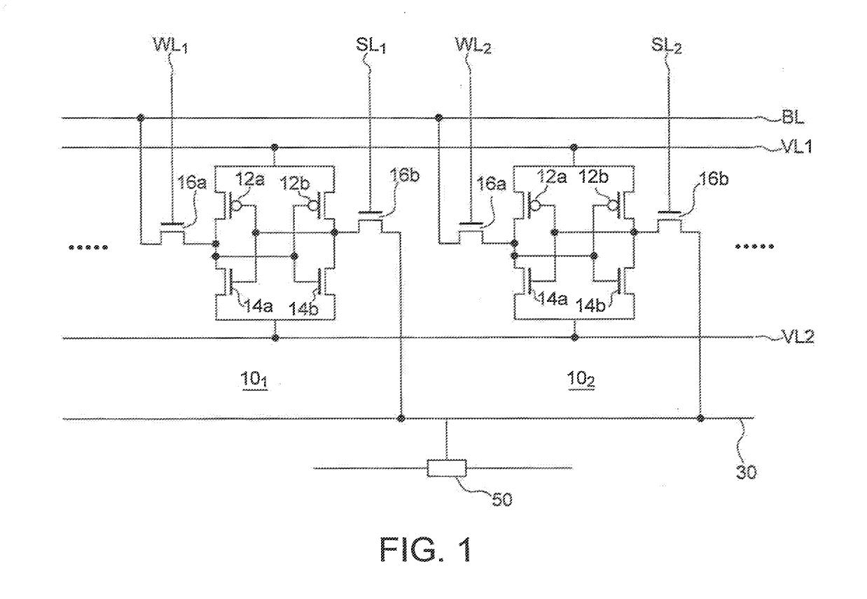

The present inventors have studied eagerly what kind of circuit configuration is possible when using an SRAM constituted by six transistors in a dynamic reconfigurable circuit. As a first reference example, a memory circuit shown in FIG. 1 is known.

The memory circuit in the first reference example shown in FIG. 1 has a plurality of memory cells. Each memory cell has one SRAM. Two memory cells are shown in FIG. 1. First and second SRAMs 10₁ and 10₂ are shown, and each SRAM constitutes a memory cell. Each of the first and second SRAMs 10₁ and 10₂ includes p-channel transistors 12a and 12b, n-channel transistors 14a and 14b, and selection transistors 16a and 16b composed of n-channel transistors. The transistors 12a and 14a constitute a first inverter circuit, and the transistors 12b and 14b constitute a second inverter circuit. The first inverter circuit and the second inverter circuit are cross-connected. In other words, an input terminal of the first inverter circuit is connected to an output terminal of the second inverter circuit, and an input terminal of the inverter is connected to an output terminal of the first inverter circuit. And the selection transistor 16a is connected at one of its source and drain to the output terminal of the first inverter circuit, and the selection transistor 16b is connected at one of its source and drain to the output terminal of the second inverter circuit.

Sources of the transistors 12a and 12b are connected to a first power supply line VL1, and sources of the transistors 14a and 14b are connected to a second power supply line VL2. The selection transistor 16a is connected at the other of its source and drain to a bit line BL, and the selection transistor 16b is connected at the other of its source and drain to an output line 30. Furthermore, the selection transistor 16a in the first SRAM 10₁ is connected at its gate to a first write selection signal line WL₁, and the selection transistor 16b in the first SRAM 10₁ is connected at its gate to a first selection signal line SL₁. The selection transistor 16a in the second SRAM 10₂ is connected at its gate to a second write selection signal line WL₂, and the selection transistor 16b in the second SRAM 10₂ is connected at its gate to a second selection signal line SL₂. Furthermore, the output line 30 is connected to a switch circuit 50.

Writing into the memory circuit according to the first reference example shown in FIG. 1 is conducted as described hereafter. Writing into the SRAM 10₁ and 10₂ is conducted by using write selection signals WL₁ and WL₂ which are independent of each other, respectively, and the common bit line BL. The bit line BL is brought to an “H” level state, and a write selection signal in an SRAM desired to output an “L” level, for example, the write selection signal WL₁ in the first SRAM 10₁ is brought to an “H” level. The bit line BL is brought to an “L” level state, and the write selection signal WL₂ in the second SRAM 10₂ desired to output an “H” level is brought to an “H” level. As a result, writing into the SRAMs 10₁ and 10₂ can be conducted. As for a read operation, the SRAM 10₁ or 10₂ is selected by using the selection signal SL₁ or SL₂ and reading is conducted.

In this way, the memory circuit according to the first reference example shown in FIG. 1 needs a total of six interconnections composed of the output line 30, the two power supply lines VL1 and VL2, the bit line BL, the selection signal line SL, and the write selection signal line WL.

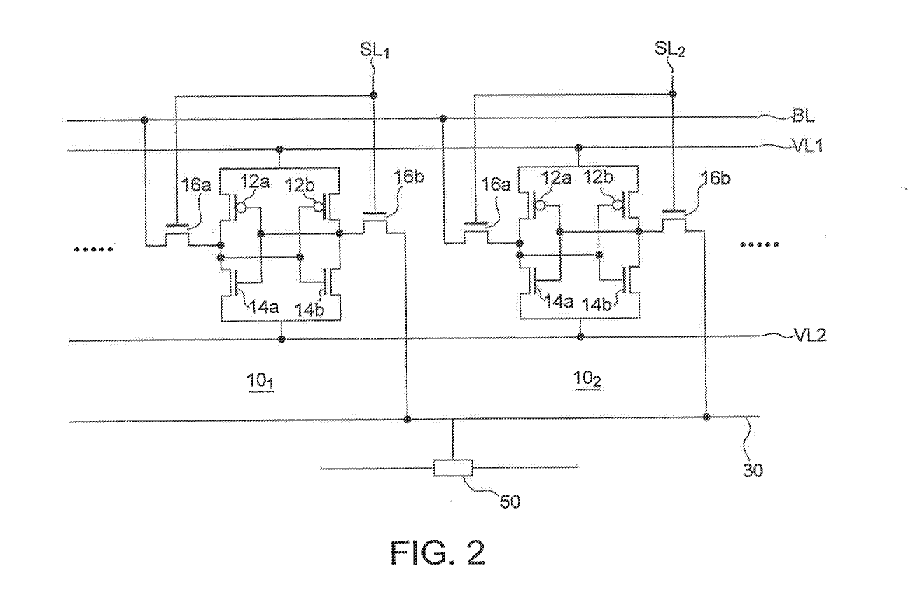

On the other hand, it is conceivable as a second reference example to make the selection signal line and the write selection signal line common as shown in FIG. 2. In other words, the gate of the selection transistor 16a in the first SRAM 10₁ is connected to the first selection signal line SL₁, and the gate of the selection transistor 16a in the second SRAM 10₂ is connected to the second selection signal line SL₂. In this case, each memory cell needs five interconnections composed of the output line 30, the first and second power supply lines VL1 and VL2, the bit line BL, and the selection signal line SL.

Writing into and reading from the memory circuit according to the second reference example shown in FIG. 2 can be conducted in the same way as the memory circuit according to the first reference example shown in FIG. 1.

However, the memory circuit according to the second reference example has two problems described hereafter.

As a first problem, there is a possibility that data will be rewritten at the time of reading. For example, in the case where an SRAM which is selected at certain time and an output of which is output to the switch circuit 50, for example, SRAM 10₁ outputs an “H” level, the bit line BL is at “L.” If an SRAM which outputs an “L” level, for example, SRAM 10₂ is selected at a subsequent time, the SRAM 10₂ must charge capacitance on the bit line BL and bring the bit line BL to the “H” level. At this time, there is a possibility that data in the SRAM 10₂ will be rewritten by a current which flows to charge the bit line BL. Therefore, it is necessary to change over the selection signal slowly enough to prevent data in a SRAM from being rewritten. It is disadvantageous to the dynamic reconfigurable circuit which needs frequent changeover.

A second problem will now be described. Since the bit line is charged and discharged by the SRAM reading as described above, it is necessary to provide a bit line in association with each switch circuit 50. For example, when reading data in two SRAMs by using one bit line, it is possible that one of the two SRAMs outputs the “L” level whereas the other outputs the “H” level. In this case, a current continues to flow from one SRAM to the other SRAM, and power is dissipated. In addition, there is a possibility that data rewriting will occur. Therefore, it is necessary to further provide a selection transistor for the bit line of each switch circuit.

As described heretofore, it is not realistic to use the circuit shown in FIG. 2 in the dynamic reconfigurable circuit. As a matter of fact, when using SRAMs, one SRAM needs as many as six power supply lines and signal lines.

Hereafter, embodiments will be described specifically with reference to the drawings.

### First Embodiment

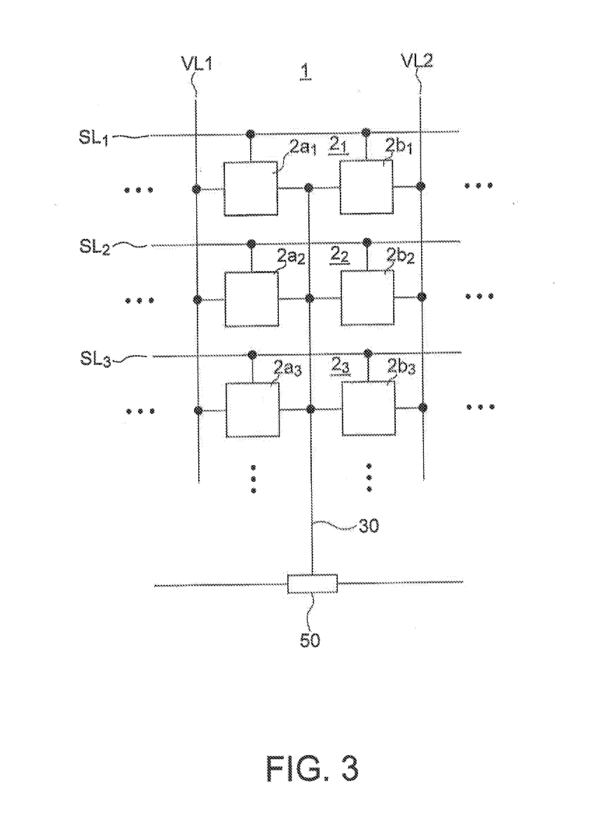

A memory circuit according to a first embodiment is shown in FIG. 3. A memory circuit 1 according to the first embodiment includes a plurality of memory cells 2₁, 2₂ and 2₃, selection signal lines SL₁, SL₂ and SL₃, first and second power supply lines V1 and V2, and a switch circuit 50. Each memory cell 2ᵢ (i=1, 2, 3) includes a pair of first and second nonvolatile memory circuits 2aᵢ and 2bᵢ. Each of the paired first and second nonvolatile memory circuits 2aᵢ and 2bᵢ (i=1, 2, 3) has first to third terminals. The first nonvolatile memory circuit 2aᵢ (i=1, 2, 3) is connected at its first terminal to the first power supply line VL1, and connected at its second terminal to an output line 30. The second nonvolatile memory circuit 2bᵢ (i=1, 2, 3) is connected at its first terminal to the second power supply line VL2, and connected at its second terminal to the output line 30. And the paired first and second nonvolatile memory circuits 2aᵢ and 2bᵢ (i=1, 2, 3) are connected at their respective third terminals to a selection signal line SLᵢ. The output line 30 is connected to the switch circuit 50.

In the memory circuit according to the first embodiment, the paired first and second nonvolatile memory circuits 2aᵢ and 2bᵢ (i=1, 2, 3) connected to the same selection signal are subject to complementary writing by using the first power supply line VL1 and the second power supply line VL2 connected to them, respectively, and the selection signal line SLᵢ. In a state in which the memory cell has information written therein, i.e., at the time of reading, one nonvolatile memory circuit, for example, the first nonvolatile memory circuit 2aᵢ is in a high resistance state, whereas the other nonvolatile memory circuit, for example, the second nonvolatile memory circuit 2bᵢ is in a low resistance state.

At the time of reading (in a stationary state), one of the first power supply line VL1 and the second power supply line VL2 is at the “H” level, whereas the other is at the “L” level. For example, if the first nonvolatile memory circuit 2aᵢ connected at its first terminal to the first power supply line VL1 is in the low resistance state and the second nonvolatile memory circuit 2bᵢ connected at its first terminal to the second power supply line VL2 is in the high resistance state, when the first power supply line VL1 is at the “H” level, the second power supply line VL2 is at the “L” level, and the selection signal line SL₁ is at a readout voltage, then an “H” level is output to the output line 30 as an output of the memory cell 2₁. If the paired nonvolatile memory circuits are in the opposite resistance states, then an “L” level is output to the output line 30 as the output of the memory cell 2₁. The switch circuit 50 is controlled by an output of the memory circuit 1.

In the first embodiment, a total of four power supply lines and signal lines composed of the output line 30, the first and second power supply lines VL1 and V12, and the selection signal line SL are provided for each memory cell, in this way. Interconnections can be reduced as compared with the case where an SRAM is used as the memory cell.

Furthermore, in the first embodiment, the memory cell has nonvolatile memory circuits. Therefore, power dissipation can be reduced. In addition, even if changeover is conducted faster than the operation frequency, it is possible to prevent the storage state of the memory cell from being changed.

Owing to the facts described heretofore, the memory circuit according to the first embodiment can be used in the dynamic reconfigurable circuit.

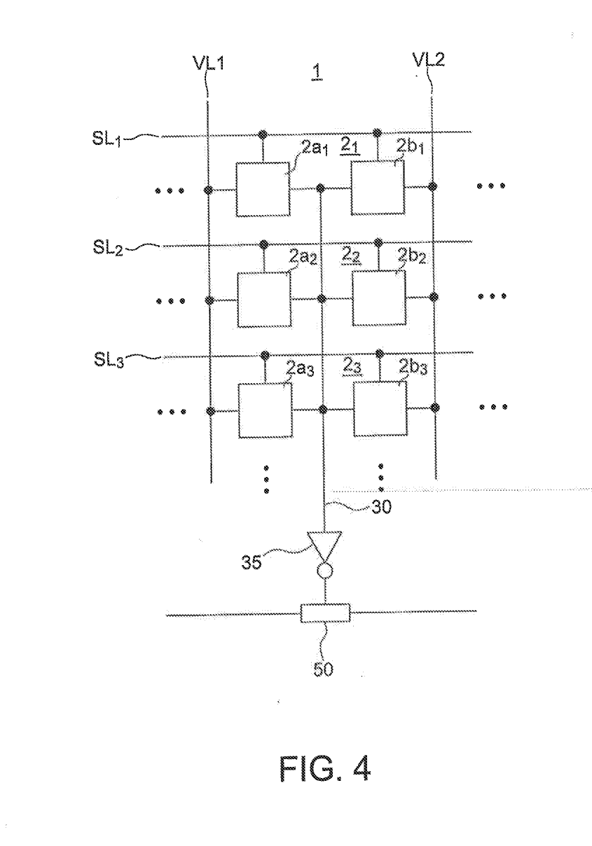

By the way, a buffer circuit 35 composed of an inverter may be provided between the output line 30 and the switch circuit 50 as in a modification of the first embodiment shown in FIG. 4. As a result, the switch circuit 50 can be controlled stably even in a case where a current at the time when the nonvolatile memory circuit is in the low resistance state is small or a current required to control the switch circuit 50 is large.

### Second Embodiment

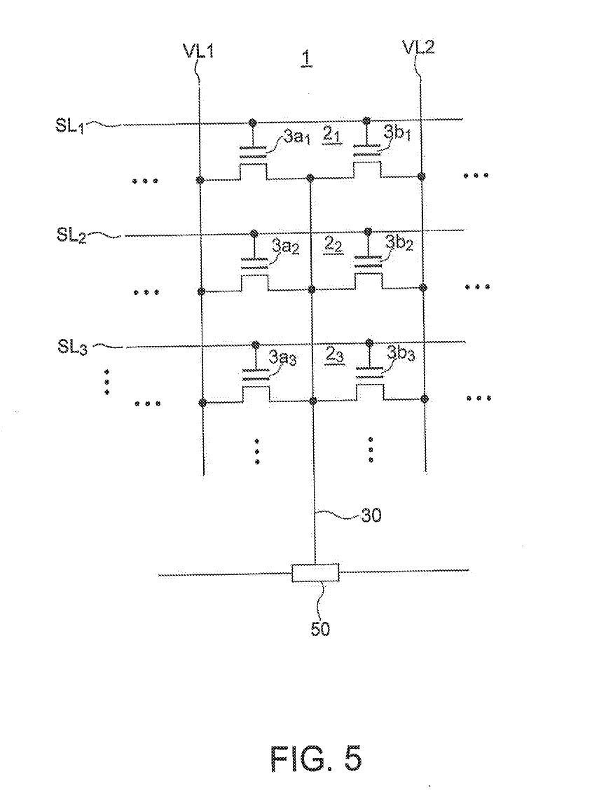

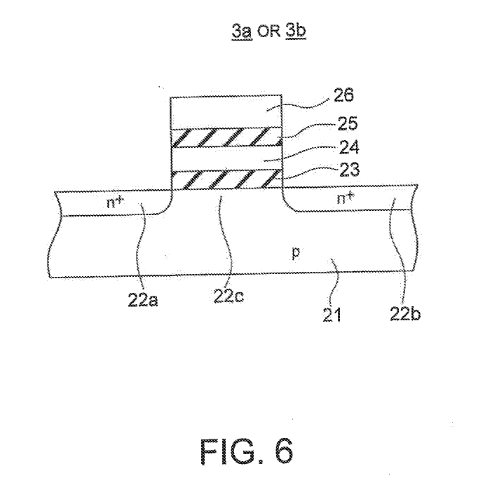

A memory circuit according to a second embodiment is shown in FIG. 5. The memory circuit 1 according to the second embodiment has a configuration in which first and second nonvolatile memory transistors 3aᵢ and 3bᵢ each having a charge storage film are used as the first and second nonvolatile memory circuits 2aᵢ and 2bᵢ (i=1, 2, 3) in the first embodiment shown in FIG. 3. As shown in FIG. 6, each of the first and second nonvolatile memory transistors 3aᵢ and 3bᵢ (i=1, 2, 3) includes, for example, an n-type source 22a and an n-type drain 22b provided at a distance in a p-type semiconductor layer 21, a tunnel insulation film 23 provided on the semiconductor layer 21 to serve as a channel 22c between the source 22a and the drain 22b, a charge storage film 24 provided on the tunnel insulation film 23, a block insulation film 25 provided on the charge storage film 24, and a control gate 26 provided on the block insulation film 25. By the way, although the memory transistor 3a or 3b shown in FIG. 6 is an n-channel memory transistor, it may be a p-channel memory transistor. The charge storage film 24 may be, for example, a floating gate made of polysilicon, or may be a trap insulation film (for example, a SiN film) which traps charge. If the charge storage film 24 is the floating gate, the memory transistor 3 is called floating gate memory transistor as well. If the charge storage film 24 is a trap insulation film having SiN as a basic constituent material, then the memory transistor 3 is called MONOS (Metal-Oxide-Nitride-Oxide-Semiconductor) memory transistor as well. If the gate electrode is polysilicon, the memory transistor is called SONOS (Silicon-Oxide-Nitride-Oxide-Silicon) memory transistor as well in some cases. Herein, this is also referred to as MONOS memory transistor.

In the second embodiment, the memory transistor 3aᵢ (i=1, 2, 3) is connected at its control gate (referred to simply as gate as well), which is a third terminal, to a selection signal line SLᵢ, connected at one of its source and drain, which is a first terminal, to a first power supply line VL1, and connected at the other of its source and drain, which is a second terminal, to an output line 30. The memory transistor 3bᵢ (i=1, 2, 3) is connected at its control gate, which is a third terminal, to the selection signal line SLᵢ, connected at one of its source and drain, which is a first terminal, to a second power supply line VL2, and connected at the other of its source and drain, which is a second terminal, to the output line 30. And paired two memory transistors sharing a selection signal, for example, the memory transistors 3a₁ and 3b₁ sharing a selection signal SL₁ are subject to complementary writing. In other words, one of the paired two memory transistors, for example, the memory transistor 3a₁ becomes high in threshold because a large number of electrons are stored in a charge storage film. The other of the paired two memory transistors, for example, the memory transistor 3b₁ becomes low in threshold because a small number of electrons are stored in a charge storage film.

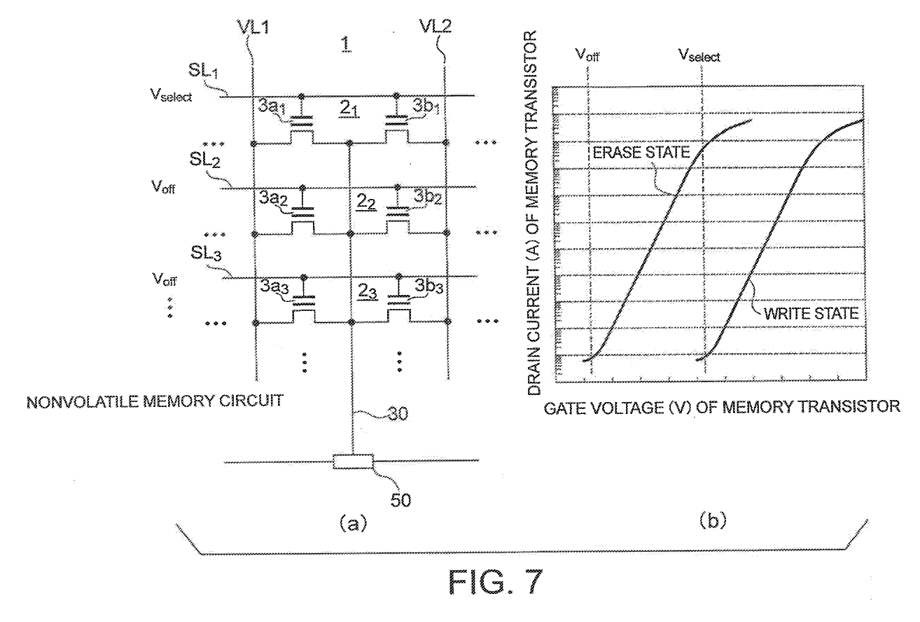

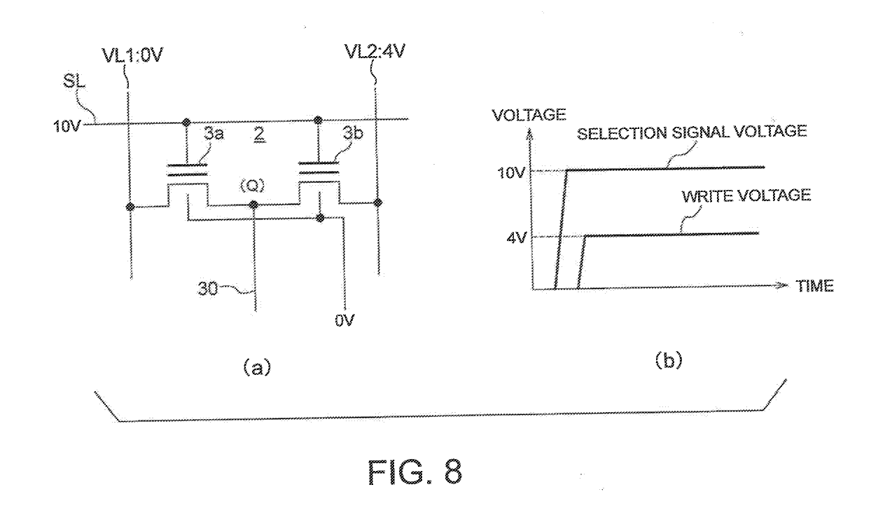

A selection method of a memory circuit in the second embodiment will now be described with reference to FIGS. 7(a) to FIG. 8(b). In the present specification, a state in which the threshold is high is defined as write state, and a state in which the threshold is low is defined as erase state as shown in FIG. 7(b). The selection signal at the time of reading is set equal to a voltage V_{select} which makes the leak of the memory transistor in the write state as small as possible and which makes the on-current of the memory transistor in the erase state as large as possible. As for a non-selection signal for memories other than a memory to be subject to reading, a voltage V_{off} which brings both memory transistors into an off-state is applied (FIG. 7(a)). The selection signal V_{select} and the non-selection signal V_{off} depend upon characteristics of the memory transistor. In particular, there is also a possibility that the non-selection signal V_{off} is a negative voltage.

If it is desired to write data selectively into the paired two memory transistors 3a and 3b which constitute a memory cell 2 as shown in FIGS. 8(a) and 8(b), then a selection signal voltage (for example, 10 V) is applied to a selection signal line SL, and a write voltage (for example, 4 V) is applied to a power supply line (for example, a second power supply line VL2) connected to a memory transistor (for example, a memory transistor 3b) to be subject to writing. By the way, 0 V is applied to a power supply line (for example, a first power supply line VL1) connected to a memory transistor (for example, a memory transistor 3a) which is not be subject to writing (FIG. 8(a)). This is a write scheme utilizing channel hot electrons as described hereafter. The channel hot electrons are electrons having extremely high energy. The channel hot electrons are generated when a drain voltage of a transistor becomes higher than a certain value and a channel causes pinch off at a drain end. Writing into the memory is implemented by pulling channel hot electrons generated by a potential difference between the source and drain into a charge storage film by the gate voltage. The write scheme using channel hot electrons has an advantage that the value of a voltage applied to each individual terminal is small as compared with a write scheme using an FN (Fowler-Nordheim) tunnel current. As for timing of applying the voltage, the selection signal voltage is applied to the selection signal line SL and then a write voltage is applied to the second power supply line VL2 (FIG. 8(b)).

The write scheme using the channel hot electrons will now be described with reference to FIGS. 8(a) and 8(b). If the selection signal voltage (10 V) is applied to the selection signal line SL, then both the first and second memory transistors 3a and 3b turn on. Since a voltage of approximately 20 V is required for the FN tunnel current, writing into both memory transistors 3a and 3b is not caused by this selection signal voltage. If a write voltage (4 V) is applied to the second power supply line VL2 in this state, a difference is caused in the gate-to-source potential (hereafter referred to as drive voltage as well) between the memory transistor 3a and the memory transistor 3b. In other words, the drive voltage is 10 V in the memory transistor 3a, whereas the drive voltage becomes 6 V in the memory transistor 3b. In general, channel resistance of a transistor becomes small as the drive voltage becomes great. Therefore, the memory transistor 3a becomes a lower resistance state as compared with the memory transistor 3b. Letting channel resistance of the memory transistor 3a be R1, channel resistance of the memory transistor 3b be R2, voltages applied to the first power supply line VL1 and the second power supply line VL2 be VBL1 and VBL2, respectively, and a potential on a memory output node Q, i.e., a potential on the output line 30 be VQ, VQ is represented by the following expression.

VQ=(R1/(R1+R2))×(VBL2−VBL1)

Since R1<R2, VQ becomes smaller than (VBL2−VBL1)/2. In other words, the potential VQ becomes a potential which is closer to the potential VBL1 than the potential VBL2. And a source-drain voltage of the memory transistor 3b becomes greater than a source-drain voltage of the memory transistor 3a.

As described earlier, channel hot electrons are generated when a channel of a transistor pinches off at the drain end. If the source-drain voltage is made great gradually, pinch off occurs when a certain voltage (Vdsat) is reached. Once pinch off occurs, the drain current of the transistor saturates.

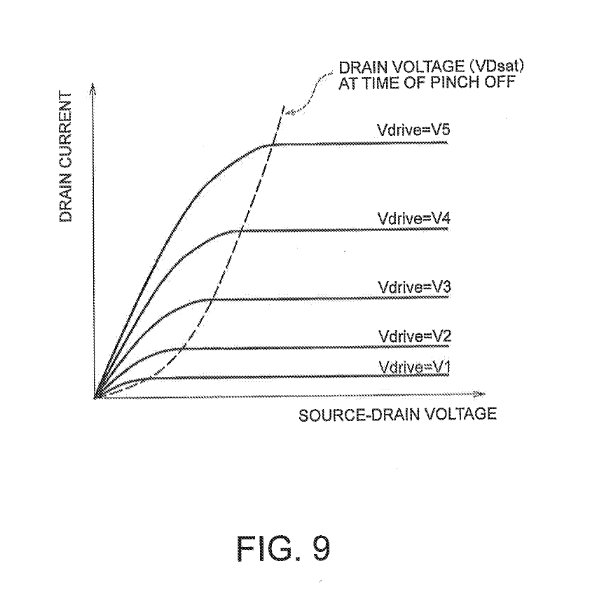

Such drain current characteristics for various drive voltages are shown in FIG. 9. In other words, FIG. 9 shows dependence of the source-drain voltage upon the drain current with various drive voltages Vdrive taken as parameters. FIG. 9 shows drain current characteristics in the case where voltages V1 to V5 of five kinds are taken as the drive voltage Vdrive. Here, V1<V2<V3<V4<V5. A dashed line represents points where the channel pinches off. In general, the saturation voltage Vdsat becomes greater as the drive voltage assumes a greater value.

In the memory circuit shown in FIG. 8(a), the drive voltage of the first memory transistor 3a is greater than the drive voltage of the second memory transistor 3b. Therefore, the first memory transistor 3a is greater, in the source-drain voltage required for pinch off as well, than the second memory transistor 3b. As described earlier, however, the source-drain voltage of the first memory transistor 3a is smaller than the source-drain voltage of the second memory transistor 3b. Therefore, the source-drain voltage required for the pinch off is not obtained in the first memory transistor 3a, and writing using channel hot electrons does not occur. On the other hand, the drive voltage is relatively small and the source-drain voltage is relatively great in the second memory transistor 3b. Therefore, pinch off of the channel occurs, memory writing using channel hot electrons occurs, and writing can be conducted selectively.

When conducting memory erasing, it is conducted by applying a negative erase voltage in a state in which a voltage of 0 V is applied to a substrate electrode (an electrode for applying a voltage to a semiconductor layer 21 in which the memory transistors 3a and 3b are formed). The erase voltage is, for example, −20 V. At this time, erasing is conducted collectively on memory cells connected to the same selection signal line SL.

In this way, in the second embodiment as well, a total of four power supply lines and signal lines composed of the output line 30, the first and second power supply lines VL1 and VL2, and the selection signal line SL are provided for each memory cell, in the same way as the first embodiment. As a result, interconnections can be reduced as compared with the case where SRAMs are used as memory cells.

Furthermore, in the second embodiment, the memory cell has nonvolatile memory transistors in the same way as the first embodiment. Therefore, power dissipation can be reduced. In addition, it is possible to prevent the storage state of the memory cell from being changed even if changeover is conducted faster than the operation frequency.

Owing to the facts described heretofore, the memory circuit according to the second embodiment can be used in the dynamic reconfigurable circuit in the same way as the first embodiment.

By the way, the buffer circuit 35 composed of an inverter can be provided between the output line 30 and the switch circuit 50 as in the modification of the first embodiment shown in FIG. 4.

### Third Embodiment

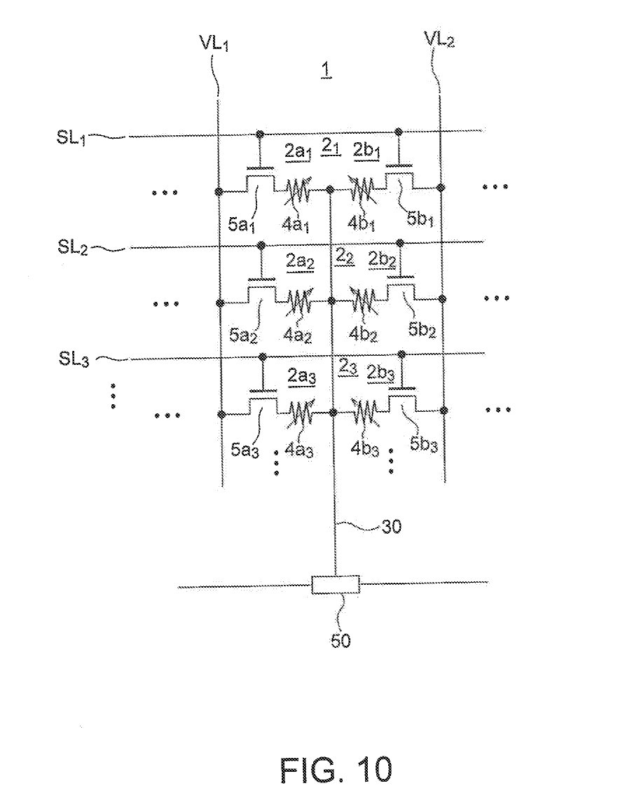

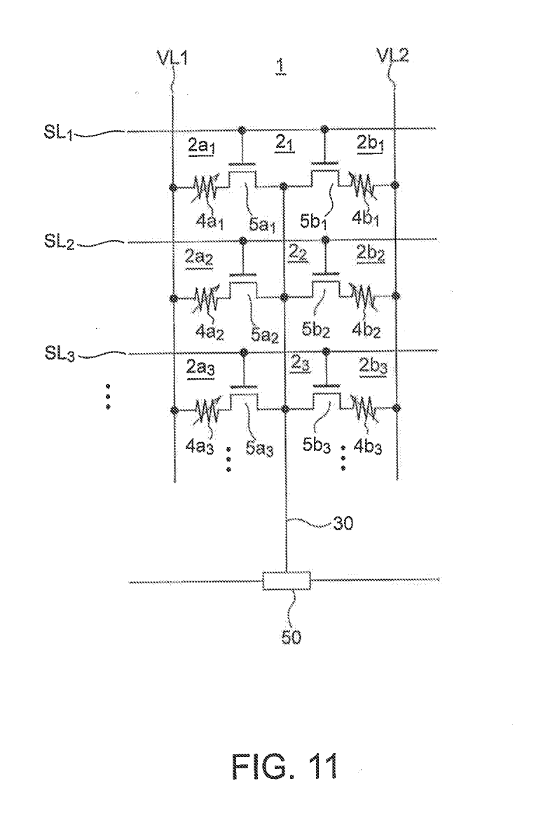

A memory circuit according to a third embodiment is shown in FIG. 10. A memory circuit 10 according to the third embodiment has a configuration obtained by using a resistance change memory element 4aᵢ and a selection transistor 5aᵢ connected in series as the first nonvolatile memory circuit 2aᵢ (i=1, 2, 3) in the first embodiment shown in FIG. 3 and using a resistance change memory element 4bᵢ and a selection transistor 5bᵢ connected in series as the second nonvolatile memory circuit 2bᵢ (i=1, 2, 3) in the first embodiment. In other words, in the first nonvolatile memory circuit 2aᵢ (i=1, 2, 3), one of terminals of the resistance change memory element 4aᵢ is connected to the output line 30 and the other of the terminals is connected to the selection transistor 5aᵢ at one of its source and drain. And the selection transistor 5aᵢ (i=1, 2, 3) is connected at the other of its source and drain to the first power supply line VL1 and connected at its gate to the selection signal line SLᵢ. In the second nonvolatile memory circuit 2bᵢ (i=1, 2, 3), one of terminals of the resistance change memory element 4bᵢ is connected to the output line 30 and the other of the terminals is connected to the selection transistor 5bᵢ at one of its source and drain. And the selection transistor 5bᵢ (i=1, 2, 3) is connected at the other of its source and drain to the second power supply line VL2 and connected at its gate to the selection signal line SLᵢ. By the way, as in a modification of the third embodiment shown in FIG. 11, arrangement of the resistance change memory element and the selection transistor in the third embodiment shown in FIG. 10 may be reversed.

As for the resistance change memory element 4aᵢ and the resistance change memory element 4bᵢ in each memory cell 2ᵢ (i=1, 2, 3), one of them is in a high resistance state and the other of them is in a low resistance state. It is possible to bring one of them into the low resistance state and the other of them into the high resistance state by conducting writing.

As the resistance change memory element, it is possible to use an MTJ (Magnetic Tunnel Junction) element having a structure in which a tunnel barrier layer is interposed between two magnetic layers, an oxidation-reduction resistance change element having a structure in which a transition metal oxide layer is interposed between two electrodes and movement of an oxygen loss in the transition metal oxide is utilized, or an ion conduction resistance change element having a structure in which, for example, a semiconductor layer is interposed between two electrodes and movement of ions of metal or the like within the semiconductor layer is utilized.

In the third embodiment as well, complementary writing is conducted into two resistance change memory elements in the same way as the first and second embodiments. In other words, in each memory cell 2ᵢ (i=1, 2, 3), writing is conducted to bring one resistance change memory element, for example, a resistance change memory element 4aᵢ into a high resistance state and bring the other resistance change memory element, for example, a resistance change memory element 4bᵢ into a low resistance state. Switch transistors 5aᵢ and 5bᵢ sharing a selection signal line SLᵢ are used to select the resistance change memory elements 4aᵢ and 4bᵢ (i=1, 2, 3). As a selection signal, a gate voltage which turns on the switch transistors 5aᵢ and 5bᵢ is used. As a non-selection signal, a gate voltage which turns off the switch transistors 5aᵢ and 5bᵢ is used.

First, a case where writing into a memory cell 2₁ is conducted will be described. In this case, the selection signal is applied to a selection signal line SL₁ connected to the memory cell 2₁, and the non-selection signal is applied to a selection signal line SL₂ connected to another memory cell 2₂. Thereupon, the selection transistors 5a₁ and 5b₁ in the memory cell 2₁ are brought into the on-state. However, the selection transistors 5a₂ and 5b₂ in the memory cell 2₂ are brought into the off-state. And, for example, a write current is flowed from the first power supply line VL1 to the second power supply line VL2 via the memory cell 2₁. Thereupon, one of the resistance change memory elements 4a₁ and 4b₁ in the memory cell 2₁ is brought into a low resistance state, and the other is brought into a high resistance state. For example, the resistance change memory element 4a₁ is brought into a low resistance state, and the resistance change memory element 4b₁ is brought into a high resistance state. To the contrary, for bringing the resistance change memory element 4a₁ into the high resistance state and bringing the resistance change memory element 4b₁ into the low resistance state, a write current is flowed from the second power supply line VL2 to the first power supply line VL1 via the memory cell 2₁ in an opposite direction. In this way, writing into each memory cell can be conducted. Writing can be conducted in the same way in both the third embodiment and its modification. By the way, a switch, for example, a transistor which turns off at the time of writing and turns on at the time of reading may be provided between the switch circuit 50 and the output line 30.

Reading from the memory subjected to the writing in this way will now be described. At the time of reading (in the stationary state), one of the first power supply line VL1 and the second power supply line VL2 is at the “H” level and the other is at the “L” level. For example, it is supposed that the first power supply line VL1 is at the “H” level and the second power supply line VL2 is at the “L” level. A selection signal is applied to the selection signal line SL₁ connected to the memory cell 2₁, and a non-selection signal is applied to the selection signal line SL₂ connected to another memory cell 2₂. Thereupon, the selection transistors 5a₁ and 5b₁ turn on, and other selection transistors turn off. As a result, an output to the switch circuit is obtained depending upon the state of the resistance change memory elements subjected to complementary writing. For example, if the resistance change memory element 4a₁ is in the low resistance state and the resistance change memory element 4b₁ is in the high resistance state, then a signal of the power supply line VL1 connected to the resistance change memory element 4a₁, i.e., the “H” level is output.

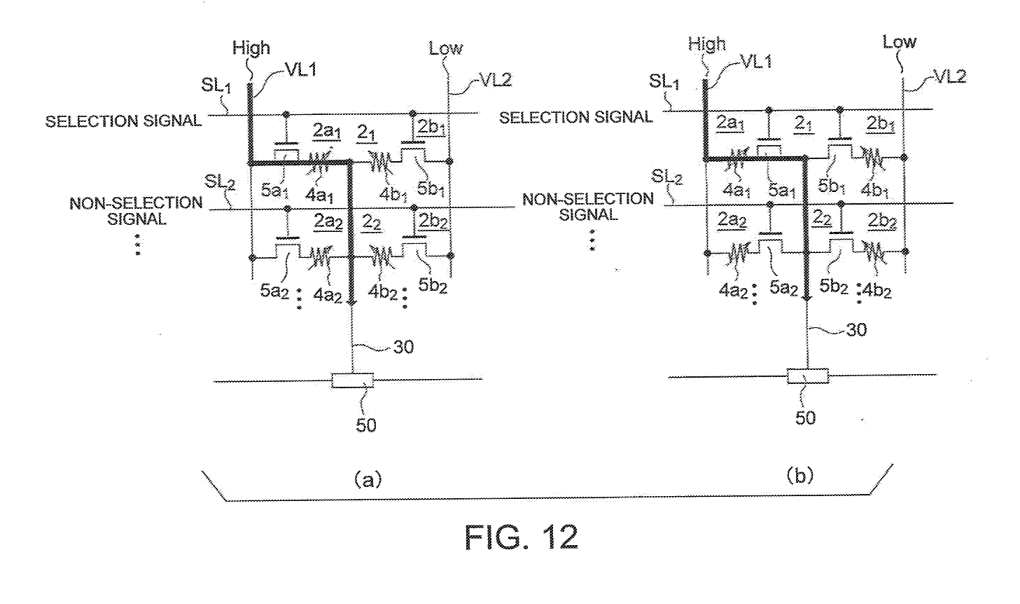

Operation of the third embodiment shown in FIGS. 10 and 11 will now be described with reference to FIGS. 12(a) and 12(b). The output line 30 of the memory repeats charging and discharging according to the selected memory cell. If the resistance change memory element is an element which is low in off resistance, it is desirable to connect a selection transistor which is higher in off-resistance than the resistance change memory element to an output side of the memory cell (FIG. 12(b)). As a result, the leak current at the time of charging can be reduced, and the power dissipation can be lowered. On the other hand, if the resistance change memory is connected on the output side, a leak current occurs in the resistance change memory in the non-selected memory circuit 2a₂, resulting in increased power dissipation (FIG. 12(a)).

In this way, in the third embodiment as well, a total of four power supply lines and signal lines composed of the output line 30, the first and second power supply lines VL1 and VL2, and the selection signal line SL are provided for each memory cell, in the same way as the first embodiment. As a result, interconnections can be reduced as compared with the case where SRAMs are used as memory cells.

Furthermore, in the third embodiment, the memory cell has the first and second nonvolatile resistance change elements which assume complementary states in the same way as the first embodiment. Therefore, power dissipation can be reduced. In addition, it is possible to prevent the storage state of the memory cell from being changed even if changeover is conducted faster than the operation frequency.

Owing to the facts described heretofore, the memory circuit according to the third embodiment can be used in the dynamic reconfigurable circuit in the same way as the first embodiment.

By the way, the buffer circuit 35 composed of an inverter can be provided between the output line 30 and the switch circuit 50 as in the modification of the first embodiment shown in FIG. 4.

### Fourth Embodiment

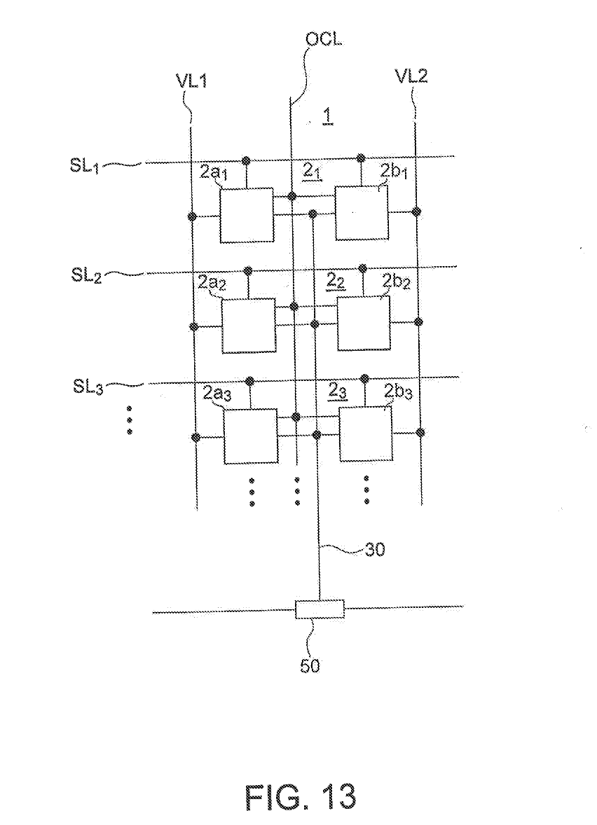

A memory circuit according to a fourth embodiment is shown in FIG. 13. In the first embodiment, a memory circuit 1 according to the fourth embodiment has a configuration in which outputs of the first and second nonvolatile memory circuits are controlled by an output control signal and an output control signal line OCL is newly provided to transmit the output control signal to the first and second nonvolatile memory circuits.

In the fourth embodiment, output signals from memory cells are interrupted by the output control signal.

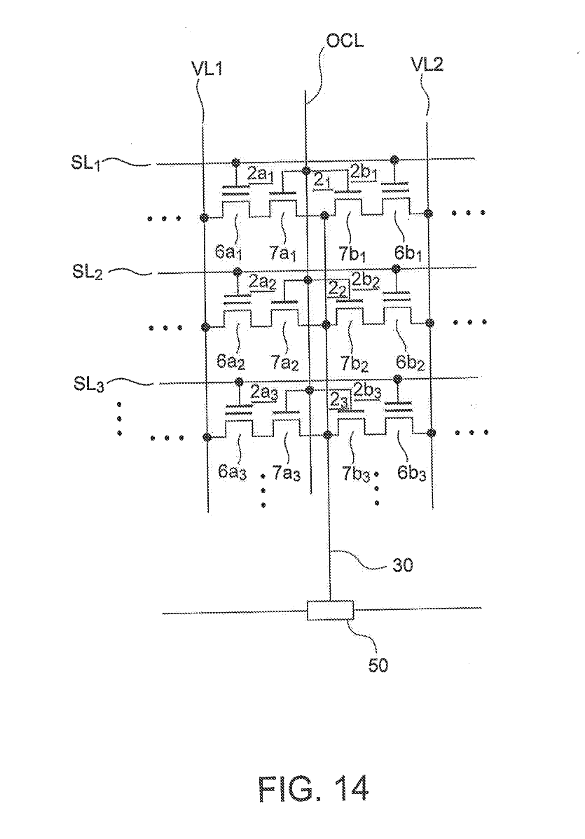

As described in the second reference example, even a memory circuit using SRAMs in the memory cell can be constituted by using five signal lines, but it is not realistic. In a first concrete example of the fourth embodiment shown in FIG. 14, each of the first and second nonvolatile memory circuits has a nonvolatile memory transistor and a selection transistor. As a result, there is no restriction that the selection signal must be changed over slowly. In addition, since nonvolatile memory transistors are used, there is no risk that data will be rewritten.

In a memory circuit 1 in the first concrete example shown in FIG. 14, each memory cell 2ᵢ (i=1, 2, 3) includes a first nonvolatile memory circuit 2aᵢ and a second nonvolatile memory circuit 2bᵢ.

The first nonvolatile memory circuit 2aᵢ (i=1, 2, 3) includes a nonvolatile memory transistor 6aᵢ and a selection transistor 7aᵢ. The nonvolatile memory transistor 6aᵢ (i=1, 2, 3) is connected at one of its source and drain to the first power supply line VL1, connected at the other of its source and drain to the selection transistor 7aᵢ at one of its source and drain, and connected at its gate to the selection signal line SLᵢ. The selection transistor 7aᵢ (i=1, 2, 3) is connected at the other of its source and drain to the output line 30 and connected at its gate to the output control signal line OCL.

On the other hand, the second nonvolatile memory circuit 2bᵢ (i=1, 2, 3) includes a nonvolatile memory transistor 6bᵢ and a selection transistor 7bᵢ. The nonvolatile memory transistor 6bᵢ (i=1, 2, 3) is connected at one of its source and drain to the second power supply line VL2, connected at the other of its source and drain to the selection transistor 7bᵢ at one of its source and drain, and connected at its gate to the selection signal line SLᵢ. The selection transistor 7bᵢ (i=1, 2, 3) is connected at the other of its source and drain to the output line 30 and connected at its gate to the output control signal line OCL. The output line 30 is connected to the switch circuit 50.

In the memory circuit according to the first concrete example of the fourth embodiment having the above-described configuration, the output control signal line OCL common to a plurality of memory cells is supplied with a voltage which turns both connected selection transistors on and an output of a memory cell is output to the output line 30, at the time of read operation. On the other hand, at the time of writing into a memory cell, voltage application to the switch circuit 50 is prevented by applying a voltage which turns the selection transistors off to the output control signal line OCL. As a result, writing using the FN tunnel current can be conducted.

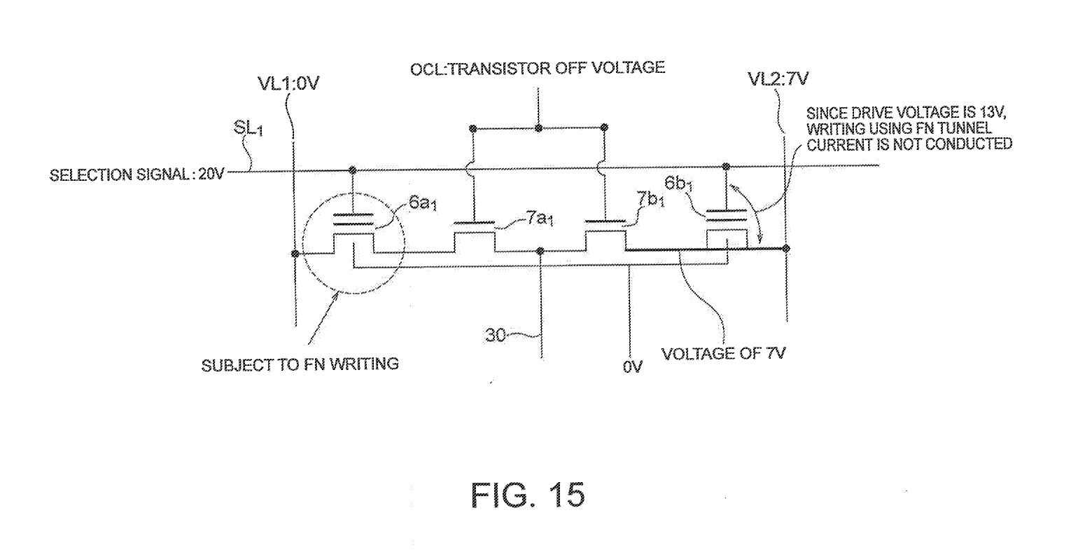

A case where writing using the FN tunnel current is conducted in the memory circuit according to the first concrete example of the fourth embodiment shown in FIG. 14 will now be described with reference to FIG. 15. A voltage which turns off the selection transistors is applied to the output control signal line. For example, 20 V is applied to a selection signal line SL₁ connected to a memory cell to be subject to writing, for example, the memory cell 2₁, the voltage on the first power supply line VL1 is set equal to 0 V, and the voltage on the second power supply line VL2 is set equal to, for example, 7V. As a result, writing into the memory transistor 6a₁ connected to the first power supply line VL1 is conducted (FIG. 15). A drive voltage of the memory transistor 6b₁ connected to the second power supply line VL2 becomes approximately 13 V, and writing using the FN current does not occur. As a matter of course, however, the memory transistor 6b₁ connected to the second power supply line VL2 is in the on-state, and the voltage of 7 V applied to the second power supply line VL2 is applied to the selection transistor 7b₁, which is brought into the off-state by the output control signal line, at one of its source and drain. Therefore, a transistor having a high gate breakdown voltage is needed as the selection transistor 7b₁. Specifically, it is considered to make the gate insulation film of the selection transistor thick or use, for example, a high-k insulation film. By the way, the high-k insulation film is an insulation film having a greater dielectric constant as compared with SiO₂, and, for example, HfO, ZrO and AlO can be mentioned.

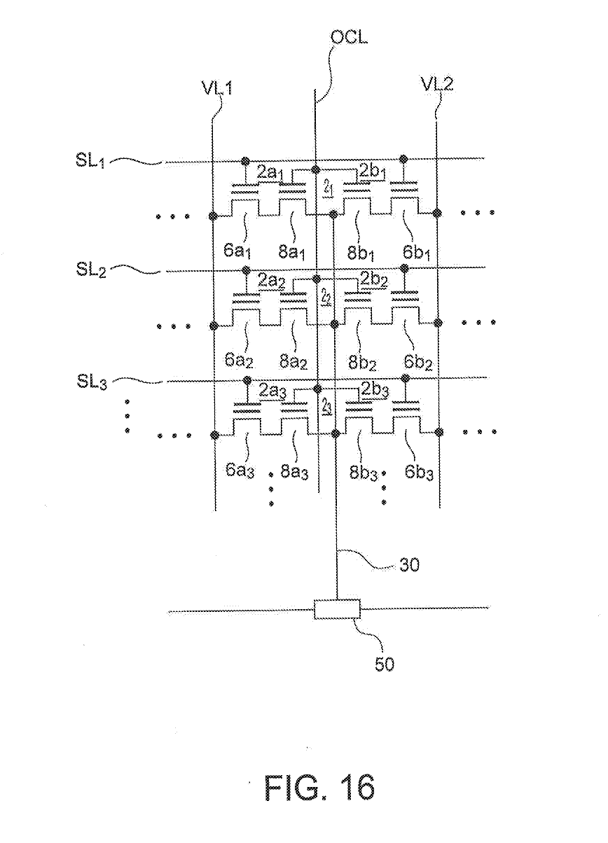

A configuration as in a memory circuit according to a second concrete example of the fourth embodiment shown in FIG. 16 may also be used. The memory circuit according to the second concrete example has a configuration obtained by replacing the selection transistors 7aᵢ (i=1, 2, 3) and 7bᵢ (i=1, 2, 3) in the memory circuit according to the first concrete example shown in FIG. 14 with nonvolatile memory transistors 8aᵢ (i=1, 2, 3) and 8bᵢ (i=1, 2, 3).

In this memory circuit according to the second concrete example, a gate voltage which turns on or off the two memory transistors 8aᵢ (i=1, 2, 3) and 8bᵢ (i=1, 2, 3) is applied to the output control signal line OCL. In each of the memory transistors 8aᵢ (i=1, 2, 3) and 8bᵢ (i=1, 2, 3), a gate has a structure in which a pluralities of layers are laminated. This brings about an advantage that the gate breakdown voltage is also high. Furthermore, it becomes possible to fabricate the memory transistors 8aᵢ (i=1, 2, 3) and 8bᵢ (i=1, 2, 3) in the same process as the memory transistors 6aᵢ (i=1, 2, 3) and 6bᵢ (i=1, 2, 3), and consequently fabrication is facilitated.

### Fifth Embodiment

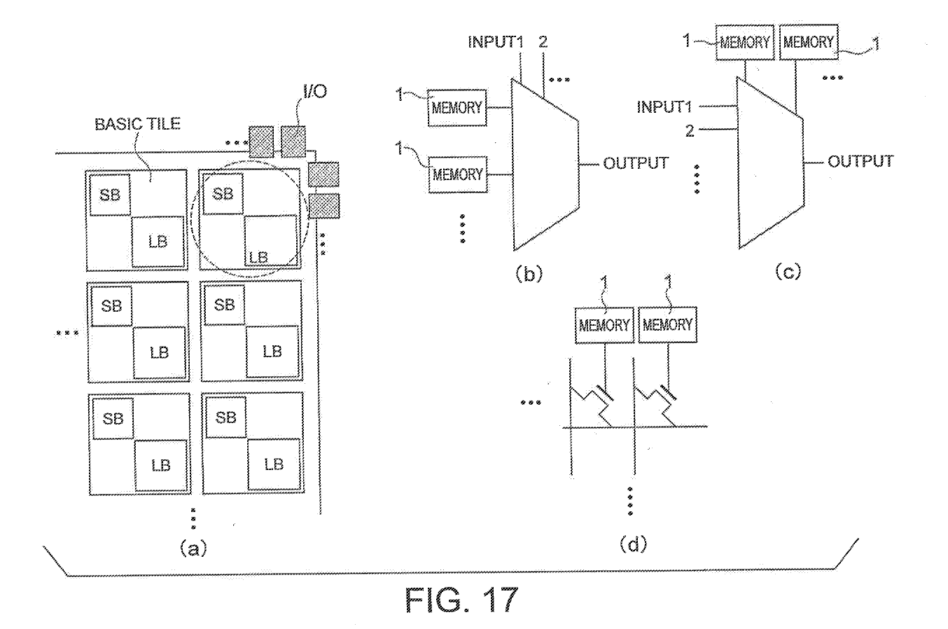

An FPGA according to a fifth embodiment is shown in FIGS. 17(a) to 17(d). As shown in FIG. 17(a), the FPGA according to the fifth embodiment has a configuration in which basic tiles each including logic blocks (hereafter referred to as LBs as well) to implement basic logic information and a switch block (hereafter referred to as SB as well) to connect LBs arbitrarily are arranged. As shown in FIGS. 17(b) to 17(d), a circuit configuring each block includes memory circuits. An arbitrary logic is implemented by the FPGA as a whole by rewriting these memory circuits.

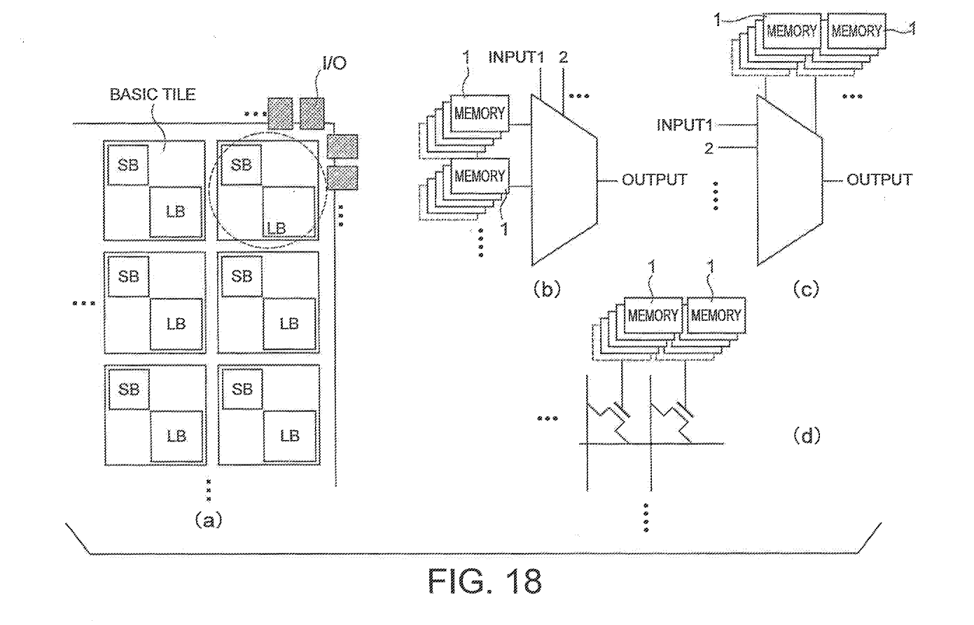

As memory circuits used in the FPGA according to the fifth embodiment, memory circuits according to the first to fourth embodiments and their modifications or concrete examples are used. By the way, in FIGS. 18(a) to 18(d), memory circuits of a plurality of kinds are included, and the memory circuits of the plurality of kinds are changed over and used. As shown in a modification shown in FIGS. 18(a) to 18(d), a configuration including a plurality of memory circuits of one kind may also be used.

Owing to such a configuration, the number of power supply lines and signal lines can be reduced and the size of the FPGA can be made small.

While certain embodiments have been described, these embodiments have been presented by way of example only, and are not intended to limit the scope of the inventions. Indeed, the novel methods and systems described herein can be embodied in a variety of other forms; furthermore, various omissions, substitutions and changes in the form of the methods and systems described herein can be made without departing from the spirit of the inventions. The accompanying claims and their equivalents are intended to cover such forms or modifications as would fall within the scope and spirit of the inventions.

What is claimed is:

1. A memory circuit comprising:
a plurality of memory cells each having one pair of first and second nonvolatile memory circuits, each of the first and second nonvolatile memory circuits having first to third terminals;
a first power supply line connected to the first terminals of the first nonvolatile memory circuits;
a second power supply line connected to the first terminals of the second nonvolatile memory circuits;
an output line to which the second terminal of the first nonvolatile memory circuit and the second terminal of the second nonvolatile memory circuit in each memory cell are connected;
a plurality of selection signal lines provided to be associated with the plurality of memory cells, the third terminal of the first nonvolatile memory circuit and the third terminal of the second nonvolatile memory circuit in an associated memory cell being connected to the associated selection signal line; and
a switch circuit connected to the output line,
each of the first and second nonvolatile memory circuits in each memory cell being capable of making a transition between a high resistance state and a low resistance state, and
in a state in which one memory cell in the plurality of memory cells has information stored therein, one of the first and second nonvolatile memory circuits in the one memory cell being in a high resistance state whereas the other being in a low resistance state.

2. The circuit according to claim 1, wherein
the first and second nonvolatile memory circuits are first and second nonvolatile memory transistors,
the first nonvolatile memory transistor is connected at one of a source and a drain thereof to the first power supply line, connected at the other of the source and drain thereof to the output line, and connected at a gate thereof to the associated selection signal line, and
the second nonvolatile memory transistor is connected at one of a source and a drain thereof to the second power supply line, connected at the other of the source and drain thereof to the output line, and connected at a gate thereof to the associated selection signal line.

3. The circuit according to claim 2, wherein the first and second nonvolatile memory transistors are floating gate nonvolatile memory transistors.

4. The circuit according to claim 2, wherein the first and second nonvolatile memory transistors are MONOS (Metal-Oxide-Nitride-Oxide-Semiconductor) nonvolatile memory transistors.

5. The circuit according to claim 1, wherein
the first nonvolatile memory circuit comprises a first resistance change memory element connected at one end thereof to one of the first power supply line and the output line, and a first selection transistor connected at one of a source and a drain thereof to the other end of the first resistance change memory element, connected at the other of the source and drain thereof to the other of the first power supply line and the output line, and connected at a gate thereof to the associated selection signal line, and
the second nonvolatile memory circuit comprises a second resistance change memory element connected at one end thereof to one of the second power supply line and the output line, and a second selection transistor connected at one of a source and a drain thereof to the other end of the second resistance change memory element, connected at the other of the source and drain thereof to the other of the second power supply line and the output line, and connected at a gate thereof to the associated selection signal line.

6. The circuit according to claim 1, further comprising an output control signal line which transmits an output control signal to control outputs of the first and second nonvolatile memory circuits.

7. The circuit according to claim 6, wherein
the first nonvolatile memory circuit comprises a first nonvolatile memory transistor connected at one of a source and a drain thereof to the first power supply line and connected at a gate thereof to the associated selection signal line, and a first selection transistor connected at one of a source and a drain thereof to the other of the source and drain of the first nonvolatile memory transistor, connected at the other of the source and drain thereof to the output line, connected at a gate thereof to the output control signal line, and
the second nonvolatile memory circuit comprises a second nonvolatile memory transistor connected at one of a source and a drain thereof to the second power supply line and connected at a gate thereof to the associated selection signal line, and a second selection transistor connected at one of a source and a drain thereof to the other of the source and drain of the second nonvolatile memory transistor, connected at the other of the source and drain thereof to the output line, connected at a gate thereof to the output control signal line.

8. The circuit according to claim 6, wherein
the first nonvolatile memory circuit comprises a first nonvolatile memory transistor connected at one of a source and a drain thereof to the first power supply line and connected at a gate thereof to the associated selection signal line, and a second nonvolatile memory transistor connected at one of a source and a drain thereof to the other of the source and drain of the first nonvolatile memory transistor, connected at the other of the source and drain thereof to the output line, connected at a gate thereof to the output control signal line, and
the second nonvolatile memory circuit comprises a third nonvolatile memory transistor connected at one of a source and a drain thereof to the second power supply line and connected at a gate thereof to the associated selection signal line, and a fourth nonvolatile memory transistor connected at one of a source and a drain thereof to the other of the source and drain of the third nonvolatile memory transistor, connected at the other of the source and drain thereof to the output line, connected at a gate thereof to the output control signal line.

9. The circuit according to claim 1, further comprising a buffer circuit provided between the output line and the switch circuit.

10. The circuit according to claim 6, further comprising a buffer circuit provided between the output line and the switch circuit.

11. A field programmable gate array comprising basic tiles each including logic blocks which implement basic logic information and a switch block which makes it possible to connect the logic blocks, at least one of the logic blocks and the switch block comprising a memory circuit according to claim 1.

12. The array according to claim 11, wherein
the first and second nonvolatile memory circuits are first and second nonvolatile memory transistors,
the first nonvolatile memory transistor is connected at one of a source and a drain thereof to the first power supply line, connected at the other of the source and drain thereof to the output line, and connected at a gate thereof to the associated selection signal line, and
the second nonvolatile memory transistor is connected at one of a source and a drain thereof to the second power supply line, connected at the other of the source and drain thereof to the output line, and connected at a gate thereof to the associated selection signal line.

13. The array according to claim 12, wherein the first and second nonvolatile memory transistors are floating gate nonvolatile memory transistors.

14. The array according to claim 12, wherein the first and second nonvolatile memory transistors are MONOS (Metal-Oxide-Nitride-Oxide-Semiconductor) nonvolatile memory transistors.

15. The array according to claim 11, wherein
the first nonvolatile memory circuit comprises a first resistance change memory element connected at one end thereof to one of the first power supply line and the output line, and a first selection transistor connected at one of a source and a drain thereof to the other end of the first resistance change memory element, connected at the other of the source and drain thereof to the other of the first power supply line and the output line, and connected at a gate thereof to the associated selection signal line, and
the second nonvolatile memory circuit comprises a second resistance change memory element connected at one end thereof to one of the second power supply line and the output line, and a second selection transistor connected at one of a source and a drain thereof to the other end of the second resistance change memory element, connected at the other of the source and drain thereof to the other of the second power supply line and the output line, and connected at a gate thereof to the associated selection signal line.

16. The array according to claim 11, further comprising an output control signal line which transmits an output control signal to control outputs of the first and second nonvolatile memory circuits.

17. The array according to claim 16, wherein
the first nonvolatile memory circuit comprises a first nonvolatile memory transistor connected at one of a source and a drain thereof to the first power supply line and connected at a gate thereof to the associated selection signal line, and a first selection transistor connected at one of a source and a drain thereof to the other of the source and drain of the first nonvolatile memory transistor, connected at the other of the source and drain thereof to the output line, connected at a gate thereof to the output control signal line, and
the second nonvolatile memory circuit comprises a second nonvolatile memory transistor connected at one of a source and a drain thereof to the second power supply line and connected at a gate thereof to the associated selection signal line, and a second selection transistor connected at one of a source and a drain thereof to the other of the source and drain of the second nonvolatile memory transistor, connected at the other of the source and drain thereof to the output line, connected at a gate thereof to the output control signal line.

18. The array according to claim 16, wherein
the first nonvolatile memory circuit comprises a first nonvolatile memory transistor connected at one of a source and a drain thereof to the first power supply line and connected at a gate thereof to the associated selection signal line, and a second nonvolatile memory transistor connected at one of a source and a drain thereof to the other of the source and drain of the first nonvolatile memory transistor, connected at the other of the source and drain thereof to the output line, connected at a gate thereof to the output control signal line, and
the second nonvolatile memory circuit comprises a third nonvolatile memory transistor connected at one of a source and a drain thereof to the second power supply line and connected at a gate thereof to the associated selection signal line, and a fourth nonvolatile memory transistor connected at one of a source and a drain thereof to the other of the source and drain of the third nonvolatile memory transistor, connected at the other of the source and drain thereof to the output line, connected at a gate thereof to the output control signal line.

19. The array according to claim 11, further comprising a buffer circuit provided between the output line and the switch circuit.

20. The array according to claim 16, further comprising a buffer circuit provided between the output line and the switch circuit.
